(19) United States
(12) Patent Application Publication
(10) Pub. No.: US 2016/0247870 A1
(43) Pub. Date: Aug. 25, 2016

(54) ORGANIC LIGHT-EMITTING DIODE DISPLAY AND METHOD OF MANUFACTURING THE SAME

(71) Applicant: Samsung Display Co., Ltd., Yongin-City (KR)

(72) Inventors: Jonghyun Park, Yongin-City (KR); Seongkweon Heo, Yongin-City (KR)

(21) Appl. No.: 14/806,013

(22) Filed: Jul. 22, 2015

(30) Foreign Application Priority Data
Feb. 24, 2015 (KR) 10-2015-0025917

(51) Int. Cl. H01L 27/32; H01L 51/56; H01L 27/12; H01L 51/52

(52) U.S. Cl. CPC H01L 27/3265; H01L 27/3246; H01L 27/3248; H01L 27/3258; H01L 27/3262; H01L 51/5218; H01L 51/5234; H01L 51/56; H01L 27/1288; H01L 2227/323

(57) ABSTRACT

An organic light-emitting diode (OLED) display and a method of manufacturing an OLED display are disclosed. In one aspect, the display includes a substrate and a thin-film transistor including an active layer, a gate electrode, a source electrode, and a drain electrode formed over the substrate. A gate insulating layer is formed between the active layer and the gate electrode, and an interlayer insulating layer is formed between the gate electrode and the source and drain electrodes. Also, a planarization layer is formed over the source and drain electrodes, and a pixel electrode is formed over the planarization layer. The display also includes capacitor including a first electrode formed on the same layer as the active layer and a second electrode formed of the same material as the pixel electrode. A pixel-defining layer covers opposing ends of the pixel electrode; an emission layer formed over the pixel electrode.

### RELATED APPLICATION

This application claims the benefit of Korean Patent Application No. 10-2015-0025917, filed on Feb. 24, 2015, in the Korean Intellectual Property Office, the disclosure of which is incorporated herein in its entirety by reference.

### BACKGROUND

1. Field

The described technology generally relates to an organic light-emitting diode display and a method of manufacturing the same.

2. Description of the Related Art

An organic light-emitting diode (OLED) display is a self-emissive display that generally includes a hole injection electrode, an electron injection electrode, and an emission layer formed therebetween. During operation, holes injected from the hole injection electrode and electrons injected from the electron injection electrode are re-combined in the emission layer so that light is emitted therefrom. The OLED display is anticipated as a next generation display due to its favorable characteristics such as low power consumption, high contrast, fast response speed, etc.

### SUMMARY OF CERTAIN INVENTIVE ASPECTS

One inventive aspect relates to an OLED display and a method of manufacturing the same.

Another aspect is an OLED display that includes a substrate; a thin-film transistor including an active layer, a gate electrode, a source electrode, and a drain electrode formed on the substrate; a gate insulating layer formed between the active layer and the gate electrode; an interlayer insulating layer formed between the gate electrode and the source and drain electrodes; a planarization layer formed on the source electrode and the drain electrode; a pixel electrode formed on the planarization layer; a capacitor including a first electrode formed from a same layer as the active layer and a second electrode formed of a same material as the pixel electrode; a pixel-defining layer covering edges of the pixel electrode; an emission layer formed on the pixel electrode; and an opposite electrode formed on the emission layer.

The first electrode can include an ion impurity-doped semiconductor.

A bottom surface of the second electrode can directly contact the gate insulating layer.

The interlayer insulating layer can include a first opening formed in the first electrode, the planarization layer can include a second opening formed in the first opening and having a width less than a width of the first opening, and the second electrode can be formed in the second opening.

The planarization layer can cover side surfaces of the first opening formed in the interlayer insulating layer.

A top surface of the second electrode can directly contact the pixel-defining layer.

The pixel electrode can include a reflective material, and the opposite electrode can include a transparent material.

The pixel electrode can include a second transparent conductive oxide layer, a transflective metal layer, and a first transparent conductive oxide layer that are sequentially stacked on the substrate.

A protective layer can be further formed on the source electrode and the drain electrode.

The protective layer can include a transparent conductive oxide.

The OLED display can further include a pad electrode formed on a same layer as the source electrode and the drain electrode.

A protective layer including a transparent conductive oxide can be further formed on the pad electrode.

A thickness of the planarization layer where the planarization layer covers edges of the pad electrode can be less than a thickness of the planarization layer where the planarization layer covers the source electrode and the drain electrode.

Another aspect is a method of manufacturing an OLED display that includes operations of performing a first mask process for forming an active layer of a thin-film transistor and a first electrode of a capacitor on a substrate; performing a second mask process for forming a gate insulating layer, forming a gate electrode of the thin-film transistor on the gate insulating layer, and forming an etching preventing layer in a region of the gate insulating layer so as to correspond to the first electrode; performing a third mask process for forming an interlayer insulating layer, and forming, in the interlayer insulating layer, a contact hole for exposing a portion of the active layer and a first opening for exposing the etching preventing layer; performing a fourth mask process for forming a source electrode and a drain electrode of the thin-film transistor on the interlayer insulating layer, and removing the etching preventing layer; performing a fifth mask process for forming a planarization layer, forming a contact hole for exposing one of the source electrode and the drain electrode in the planarization layer, and forming a second opening in the first opening; performing a sixth mask process for forming a pixel electrode on the planarization layer, and forming a second electrode of the capacitor in the second opening; and performing a seventh mask process for forming a pixel-defining layer for covering edges of the pixel electrode, and the second electrode.

After the operation of performing the second mask process, the method can further include an operation of doping a resultant of the second mask process with ion impurities on.

In the third mask process, the contact hole and the first opening can be formed by dry etching.

After the operation of performing the fourth mask process, the method can further include an operation of doping a resultant of the fourth mask process with ion impurities.

In the fourth mask process, a pad electrode can be further formed along with the source electrode and the drain electrode.

A thickness of the planarization layer where the planarization layer covers edges of the pad electrode can be less than a thickness of the planarization layer where the planarization layer covers the source electrode and the drain electrode.

After the operation of performing the seventh mask process, the method can further include operations of forming an emission layer on the pixel electrode; and forming an opposite electrode on the emission layer.

Another aspect is an organic light-emitting diode (OLED) display, comprising: a substrate; a thin-film transistor comprising an active layer, a gate electrode, a source electrode, and a drain electrode formed over the substrate; a gate insulating layer formed between the active layer and the gate electrode; an interlayer insulating layer formed between the gate electrode and the source and drain electrodes; a planarization layer formed over the source and drain electrodes; a pixel electrode formed over the planarization layer; a capacitor comprising a first electrode formed on the same layer as the active layer and a second electrode formed of the same material as the pixel electrode; a pixel-defining layer covering opposing ends of the pixel electrode; an emission layer formed over the pixel electrode; and an opposite electrode formed over the emission layer.

In the above OLED display, the first electrode includes an ion impurity-doped semiconductor.

In the above OLED display, a bottom surface of the second electrode contacts the gate insulating layer.

In the above OLED display, a first opening is formed in the interlayer insulating layer and formed over the first electrode, wherein a second opening is formed in the first opening and has a bottom surface having a width that is less than a width of a bottom surface of the first opening, and wherein the second electrode is formed in the second opening.

In the above OLED display, the planarization layer covers side surfaces of the first opening.

In the above OLED display, a top surface of the second electrode contacts the pixel-defining layer.

In the above OLED display, the pixel electrode is formed of a reflective material, wherein the opposite electrode is formed of a transparent material.

In the above OLED display, the pixel electrode comprises a second transparent conductive oxide layer, a transflective metal layer, and a first transparent conductive oxide layer that are sequentially stacked over the substrate.

The above OLED display further comprises a protective layer is formed over the source and drain electrodes.

In the above OLED display, the protective layer is formed of a transparent conductive oxide.

The above OLED display further comprises a pad electrode formed on the same layer as the source and drain electrodes.

The above OLED display further comprises a protective layer formed of a transparent conductive oxide and formed over the pad electrode.

In the above OLED display, the thickness of the planarization layer where the planarization layer is formed over opposing sides of the pad electrode is less than the thickness of the planarization layer where the planarization layer is formed over the source and drain electrodes.

Another aspect is a method of manufacturing an organic light-emitting diode (OLED) display, the method comprising: performing a first mask process including forming an active layer of a thin-film transistor and a first electrode of a capacitor over a substrate; performing a second mask process including forming a gate insulating layer, forming a gate electrode of the thin-film transistor over the gate insulating layer, and forming an etching preventing layer in a region of the gate insulating layer corresponding to the first electrode; performing a third mask process including forming an interlayer insulating layer, forming a contact hole in the interlayer insulating layer so as to expose a portion of the active layer, and forming a first opening in the interlayer insulating layer so as to expose the etching preventing layer; performing a fourth mask process including forming source and drain electrodes of the thin-film transistor over the interlayer insulating layer, and removing the etching preventing layer; performing a fifth mask process including forming a planarization layer, forming a contact hole so as to expose one of the source and drain electrodes in the planarization layer, and forming a second opening in the first opening; performing a sixth mask process including forming a pixel electrode over the planarization layer and forming a second electrode of the capacitor in the second opening; and performing a seventh mask process of forming a pixel-defining layer so as to cover the second electrode and opposing sides of the pixel electrode.

The above method further comprises doping a resultant of the second mask process with ion impurities following the performing of the second mask process.

In the above method, in the third mask process, dry etching the interlayer insulating layer so as to form the contact hole and the first opening.

The above method further comprises doping a resultant of the fourth mask process with ion impurities following the performing of the fourth mask process.

In the above method, the performing of the fourth mask process further includes forming a pad electrode concurrently with the source and drain electrodes.

In the above method, the thickness of the planarization layer where the planarization layer is formed over opposing sides of the pad electrode is less than the thickness of the planarization layer where the planarization layer is formed over the source and drain electrodes.

The above method further comprises: forming an emission layer over the pixel electrode following the performing of the seventh mask process; and forming an opposite electrode over the emission layer.

### BRIEF DESCRIPTION OF THE DRAWINGS

FIG. 1 illustrates a plan view of an OLED display according to an exemplary embodiment.

FIG. 2 illustrates a cross-sectional view illustrating a portion of an emission pixel and a portion of a pad of the OLED display according to the exemplary embodiment.

FIG. 3 illustrates a cross-sectional view illustrating a first mask process for the OLED display, according to an exemplary embodiment.

FIGS. 4A and 4B illustrate cross-sectional views illustrating a second mask process for the OLED display, according to an exemplary embodiment.

FIG. 5 illustrates a cross-sectional view of a resultant of a third mask process for the OLED display, according to an exemplary embodiment.

FIGS. 6A and 6B illustrate cross-sectional views illustrating a fourth mask process for the OLED display, according to an exemplary embodiment.

FIG. 7 illustrates a cross-sectional view illustrating a fifth mask process for the OLED display, according to an exemplary embodiment.

FIG. 8 illustrates a cross-sectional view illustrating a sixth mask process for the OLED display, according to an exemplary embodiment.

FIG. 9 illustrates a cross-sectional view illustrating a seventh mask process for the OLED display, according to an exemplary embodiment.

### DETAILED DESCRIPTION OF CERTAIN INVENTIVE EMBODIMENTS

As the described technology allows for various changes and numerous embodiments, particular embodiments will be illustrated in the drawings and described in detail in the written description. Effects and features of the described technology and methods of accomplishing the same can be understood more readily by reference to the following detailed description of exemplary embodiments and the accompanying drawings. The described technology can, however, be embodied in many different forms and should not be construed as being limited to the embodiments set forth herein.

Hereinafter, one or more exemplary embodiments will be described below in more detail with reference to the accompanying drawings. Those components that are the same or are in correspondence are rendered the same reference numeral regardless of the figure number, and redundant explanations are omitted.

Hereinafter, in one or more exemplary embodiments, while such terms as “first,” “second,” etc., can be used, but such components must not be limited to the above terms, and the above terms are used only to distinguish one component from another.

Hereinafter, in one or more exemplary embodiments, a singular form can include plural forms, unless there is a particular description contrary thereto.

Hereinafter, in one or more exemplary embodiments, terms such as “comprise” or “comprising” are used to specify existence of a recited feature or component, not excluding the existence of one or more other recited features or one or more other components.

Hereinafter, in one or more exemplary embodiments, it will also be understood that when an element such as layer, region, or component is referred to as being “on” another element, it can be directly on the other element, or intervening elements such as layer, region, or component can also be interposed therebetween.

In the drawings, for convenience of description, the sizes of layers and regions are exaggerated for clarity. For example, a size and thickness of each element can be random for convenience of description, thus, one or more exemplary embodiments are not limited thereto.

As used herein, the term “and/or” includes any and all combinations of one or more of the associated listed items. In this disclosure, the term “substantially” includes the meanings of completely, almost completely or to any significant degree under some applications and in accordance with those skilled in the art. The term “connected” can include an electrical connection.

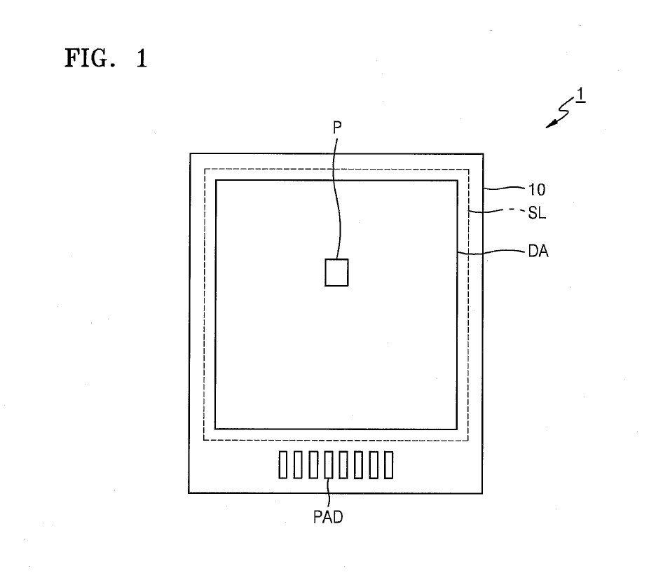

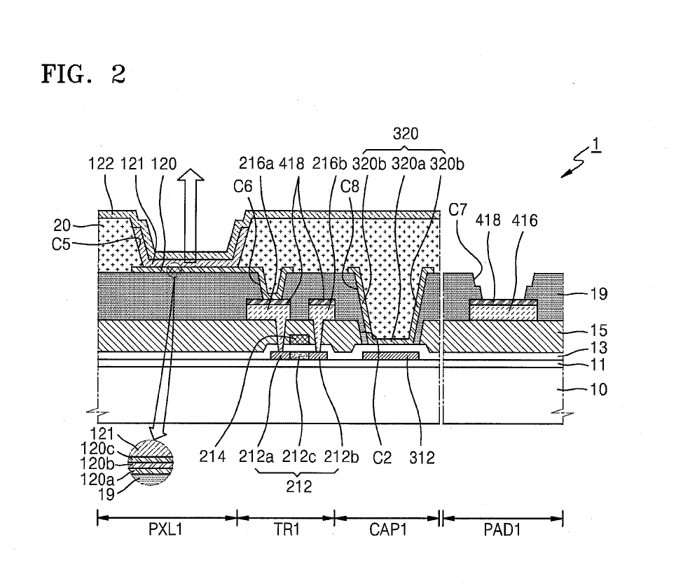

FIG. 1 illustrates a plan view of an OLED display 1 according to an exemplary embodiment. FIG. 2 illustrates a cross-sectional view illustrating a portion of an emission pixel and a portion of a pad of the OLED display 1 according to the first exemplary embodiment.

Referring to FIG. 1, the OLED display 1 includes a display area DA on a substrate 10, and the display area DA includes a plurality of pixels P and thus displays an image. The display area DA is formed within a sealing line SL, and an encapsulation member (not shown) is arranged to encapsulate the display area DA along the sealing line SL.

Referring to FIG. 2, a pixel region PXL1 having at least one emission layer 121, a thin-film transistor region TR1 having at least one thin-film transistor, a capacitor region CAP1 having at least one capacitor, and a pad region PAD1 are arranged on the substrate 10.

In the thin-film transistor region TR1, an active layer 212 of the thin-film transistor is arranged above the substrate 10 and a buffer layer 11.

The substrate 10 can be a transparent substrate including a glass substrate, a plastic substrate including polyethylene terephthalate (PET), polyethylene naphthalate (PEN), polyimide, or the like.

The buffer layer 11 can be further arranged on the substrate 10 so as to form a planar surface on the substrate 10 and to prevent penetration of foreign substances. The buffer layer 11 can be formed as a single layer or a multilayer formed of silicon nitride and/or silicon oxide.

The active layer 212 is arranged on the buffer layer 11 in the thin-film transistor region TR1. The active layer 212 can be formed of a semiconductor including amorphous silicon or polysilicon.

The active layer 212 can include a channel region 212c, and a source region 212b and a drain region 212a that are arranged at both sides of the channel region 212c and are doped with impurity. A material of the active layer 212 is not limited to amorphous silicon or polysilicon and can include an oxide semiconductor.

A gate insulating layer 13 is arranged on the active layer 212. The gate insulating layer 13 can be formed as a single layer or a multilayer including silicon nitride and/or silicon oxide.

A gate electrode 214 is arranged on the gate insulating layer 13. The gate electrode 214 can be formed as a single layer or multiple layers formed of at least one metal material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu).

Although not illustrated in FIG. 2, a wiring such as a scan line can be formed on the same layer as the gate electrode 214 by using the same material as the gate electrode 214.

As the size of a screen of the OLED display 1 is increased, a thickness of the wiring usually increases so as to prevent a signal delay due to the large screen. In the present embodiment, a thickness of the gate electrode 214 and the wiring can be set between about 6,000 Å and about 12,000 Å. When the thickness of the gate electrode 214 and the wiring is substantially equal to or greater than about 6,000 Å, the signal delay can be prevented in a large screen of at least about 50 inches. And it is difficult to form, via deposition, the thickness of the gate electrode 214 and the wiring to be greater than about 12,000 Å. The above range can provide an optimum balance between reducing signal delay and reducing difficulty in deposition.

An interlayer insulating layer 15 is deposited on the gate electrode 214. The interlayer insulating layer 15 can be formed as a single layer or multiple layers formed of silicon nitride and/or silicon oxide.

A source electrode 216b and a drain electrode 216a are arranged on the interlayer insulating layer 15. Each of the source electrode 216b and the drain electrode 216a can be formed as a single layer or multiple layers formed of at least one metal material selected from aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), copper (Cu), and an alloy thereof.

A protective layer 418 is formed on the source electrode 216b and the drain electrode 216a. The protective layer 418 prevents the source electrode 216b and the drain electrode 216a from being exposed to an etchant while a pixel electrode 120 is etched, so that a defect can be prevented.

Since the protective layer 418 and the source electrode 216b, and the protective layer 418 and the drain electrode 216a are etched by using the same mask, etched surfaces of edges of the protective layer 418 and the source electrode 216b can be equal to each other, and etched surfaces of edges of the protective layer 418 and the drain electrode 216a can be equal to each other.

A planarization layer 19 that covers the source electrode 216b and the drain electrode 216a is formed on the source electrode 216b and the drain electrode 216a. The planarization layer 19 can include polymer derivatives having commercial polymers (PMMA and PS) and a phenol group, an acryl-based polymer, an imide-based polymer, an allyl ether-based polymer, an amide-based polymer, a fluorine-based polymer, a p-xylene-based polymer, a vinyl alcohol-based polymer, or a combination thereof.

The pixel electrode 120 is arranged on the planarization layer 19. The pixel electrode 120 contacts one of the source electrode 216b and the drain electrode 216a via a contact hole C6 formed in the planarization layer 19. Referring to FIG. 2, the pixel electrode 120 contacts the drain electrode 216a, but embodiments are not limited thereto. That is, the pixel electrode 120 can contact the source electrode 216b.

The pixel electrode 120 can be formed of a reflective material. The pixel electrode 120 can include a transflective metal layer 120b. Also, the pixel electrode 120 can further include a first transparent conductive oxide layer 120a and a second transparent conductive oxide layer 120c that are formed below and on the transflective metal layer 120b, respectively.

The transflective metal layer 120b can be formed of Ag or a silver alloy. The transflective metal layer 120b and an opposite electrode 122 that is a transmissive electrode to be described later can form a micro-cavity structure and thus can improve a luminescent efficiency of the OLED display 1.

Each of the first and second transparent conductive oxide layers 120a and 120c can be formed of at least one material selected from indium tin oxide (ITO), indium zinc oxide (IZO), zinc oxide (ZnO), indium oxide (In₂O₃), indium gallium oxide (IGO), and aluminum zinc oxide (AZO). The first transparent conductive oxide layer 120a can reinforce adhesion of the planarization layer 19 and the transflective metal layer 120b, and the second transparent conductive oxide layer 120c can function as a barrier layer for protecting the transflective metal layer 120b.

A metal material such as silver that is highly reducible and forms the transflective metal layer 120b can cause a problem by which a silver particle is extracted while the pixel electrode 120 is etched. The extracted silver particle can be a main factor of a particle defect that causes a dark spot. While the pixel electrode 120 including silver is etched, if the source electrode 216b, the drain electrode 216a, a pad electrode 416, or other wiring is exposed to an etchant, silver ion that is highly reducible can receive an electron from the aforementioned metal materials and can be re-extracted as a silver particle. However, in the OLED display 1 according to the present embodiment, the source electrode 216b, the drain electrode 216a, and the pad electrode 416 are protected by the protective layer 418 and thus are not exposed to the etchant. Therefore, the defect due to the re-extraction of the silver particle can be prevented.

The edges of the pixel electrode 120 are covered by a pixel-defining layer 20. The pixel-defining layer 20 can be formed of polymer derivatives having commercial polymers (PMMA and PS) and a phenol group, an acryl-based polymer, an imide-based polymer, an allyl ether-based polymer, an amide-based polymer, a fluorine-based polymer, a p-xylene-based polymer, a vinyl alcohol-based polymer, or a combination thereof.

An intermediate layer (not shown) that includes the emission layer 121 is arranged on the pixel electrode 120 whose top surface is exposed by an opening C5 formed in the pixel-defining layer 20. The emission layer 121 can be formed of a small molecule organic material or a polymer organic material.

If the emission layer 121 is formed of the small molecule organic material, the intermediate layer can further include a hole transport layer (HTL), a hole injection layer (HIL), an electron transport layer (ETL), or an electron injection layer (EIL). In addition to these layers, if required, the intermediate layer can further include various layers. Here, various organic materials including copper phthalocyanine (CuPc), N,N′-Di(naphthalene-1-yl)-N,N-diphenyl-benzidine (NPB), tris-8-hydroxyquinoline aluminum)(Alq3), or the like can be used.

If the emission layer 121 is formed of the polymer organic material, the intermediate layer can further include an HTL. The HTL can be formed of poly-(2,4)-ethylene-dihydroxy thiophene (PEDOT) or polyaniline (PANI). Here, the polymer organic material can include poly-phenylene vinylene (PPV), polyfluorene, or the like. Also, an inorganic material can be further arranged between the emission layer 121 and pixel electrode 120 and can be further arranged between the emission layer 121 and the opposite electrode 122.

Referring to FIG. 2, the emission layer 121 is formed in a second opening C8, but this is only for convenience of description and one or more exemplary embodiments are not limited thereto. The emission layer 121 can be formed not only in the second opening C8 but can also extend to a top surface of the pixel-defining layer 20 along an etched surface of the second opening C8 formed in the pixel-defining layer 20.

The opposite electrode 122 that is commonly formed in pixels is arranged on the emission layer 121. In the OLED display 1 according to the present embodiment, the pixel electrode 120 is used as an anode and the opposite electrode 122 is used as a cathode, but polarities of the electrodes can be switched.

The opposite electrode 122 can be the transmissive electrode formed of a transparent material. The opposite electrode 122 can be formed of at least one material selected from Al, Mg, Li, Ca, LiF/Ca, and LiF/Al and can have an appropriate thickness sufficient to transmit light. Light that is emitted from the emission layer 121 is reflected from the pixel electrode 120, passes through the opposite electrode 122 that is the transmissive electrode, and is discharged in a direction away from the substrate 10.

In some embodiments, the opposite electrode 122 is not separately formed in each pixel but can be a common electrode that wholly covers the display area DA (refer to FIG. 1).

A capacitor formed in the capacitor region CAP1 includes a first electrode 312 formed on the same layer as the active layer 212 and a second electrode 320 formed of the same material as the pixel electrode 120. The gate insulating layer 13 formed between the first electrode 312 and the second electrode 320 operates as a dielectric layer.

The first electrode 312 can be formed of the same material as the active layer 212. In more detail, the first electrode 312 can include a semiconductor that is doped with ion impurities. The ion impurities can be the same as the ion impurities included in the source electrode 216b and the drain electrode 216a of the thin-film transistor.

The gate insulating layer 13 is formed on the first electrode 312. The second electrode 320 of the capacitor is formed on the gate insulating layer 13 and directly contacts the gate insulating layer 13.

The gate insulating layer 13 formed between the active layer 212 and the gate electrode 214 of the thin-film transistor extends to the capacitor region CAP1, and thus is also formed between the first electrode 312 and the second electrode 320. Accordingly, the gate insulating layer 13 operates as the dielectric layer of the capacitor.

The interlayer insulating layer 15 formed between the gate electrode 214 and the source and drain electrodes 216b and 216a of the thin-film transistor is removed from a region on the first electrode 312 in the capacitor region CAP1. A first opening C2 is formed in the region from which the interlayer insulating layer 15 is removed. Accordingly, in the present embodiment, the interlayer insulating layer 15 does not operate as a dielectric layer of the capacitor.

The planarization layer 19 formed between the source and drain electrodes 216b and 216a of the thin-film transistor and the pixel electrode 120 is removed from a region on the first electrode 312 in the capacitor region CAP1. The second opening C8 is formed in the region from which the planarization layer 19 is removed.

The second opening C8 is formed inside the first opening C2 and has a width less than a width of the first opening C2. That is, the planarization layer 19 is formed to cover side surfaces of the first opening C2 formed in the interlayer insulating layer 15. Since the planarization layer 19 is removed from the region on the first electrode 312, in the present embodiment, the planarization layer 19 does not operate as a dielectric layer of the capacitor.

Therefore, in the capacitor of the present embodiment, the first electrode 312 is formed of the same material as the doped active layer 212, the second electrode 320 is formed of the same material as the pixel electrode 120, and only the gate insulating layer 13 is used as the dielectric layer, thus, the capacitance of the capacitor can be increased. If the capacitance of the capacitor is increased, it is possible to satisfy a demand for a capacitor having a large capacitance due to a complicated driving circuit for driving an OLED display.

The second electrode 320 of the capacitor is formed in the second opening C8 formed in the planarization layer 19. The second electrode 320 is formed of the same material as the pixel electrode 120. As will be described later, the second electrode 320 and the pixel electrode 120 are formed in a same photo mask process.

The second opening C8 formed from an organic insulting layer is patterned by dry etching, and covers an etched surface of the first opening C2 having a sharp slope and a rough surface, so that the second electrode 320 can be effectively formed in the second opening C8.

The second electrode 320 includes a first portion 320a formed on a bottom of the second opening C8, and a second portion 320b formed on each of side surfaces of the second opening C8.

One surface of the first portion 320a directly contacts the gate insulating layer 13, and the other surface of the first portion 320a directly contacts the pixel-defining layer 20. One surface of the second portion 320b directly contacts the planarization layer 19, and the other surface of the first portion 320a directly contacts the pixel-defining layer 20.

In the pad region PAD1 that is an outer region of the display area DA, the pad electrode 416 that is a connection terminal of an external driver is positioned.

The pad electrode 416 is formed on the interlayer insulating layer 15, and edges of the pad electrode 416 are covered with the planarization layer 19.

The pad electrode 416 is formed of the same material as the source electrode 216b and the drain electrode 216a, and the protective layer 418 is formed on the pad electrode 416. The protective layer 418 prevents the pad electrode 416 from being exposed to an etchant while the pixel electrode 120 is etched, so that a particle defect can be prevented. Also, the protective layer 418 prevents the pad electrode 416 from being exposed to moisture and oxygen, so that it is possible to prevent reliability of a pad from deteriorating.

Since the protective layer 418 and the pad electrode 416 are etched by using the same mask, etched surfaces of edges of the protective layer 418 and the pad electrode 416 can be substantially equal to each other.

A thickness of the planarization layer 19 where the planarization layer 19 covers the edges of the pad electrode 416 is less than a thickness of the planarization layer 19 where the planarization layer 19 covers the source electrode 216b and the drain electrode 216a in the thin-film transistor region TR1, and is less than a thickness of the planarization layer 19 where the planarization layer 19 is between the interlayer insulating layer 15 and the pixel electrode 120 in the pixel region PXL1.

The planarization layer 19 covers the edges of the pad electrode 416 and thus prevents deterioration of the edges of the pad electrode 416. However, if the thickness of the planarization layer 19 where the planarization layer 19 covers the edges of the pad electrode 416 is large, a connection error can occur at the pad electrode 416 when the external driver is connected, and thus, the thickness of the planarization layer 19 where the planarization layer 19 covers the edges of the pad electrode 416 can be small.

Although not illustrated in FIG. 2, the OLED display 1 can further include an encapsulation member (not shown) that encapsulates the pixel region PXL1, the capacitor region CAP1, and the thin-film transistor region TR1. The encapsulation member can be formed as a substrate including a glass material, a metal film, or an encapsulation thin film formed of an organic insulating film and an inorganic insulating film that are alternately stacked.

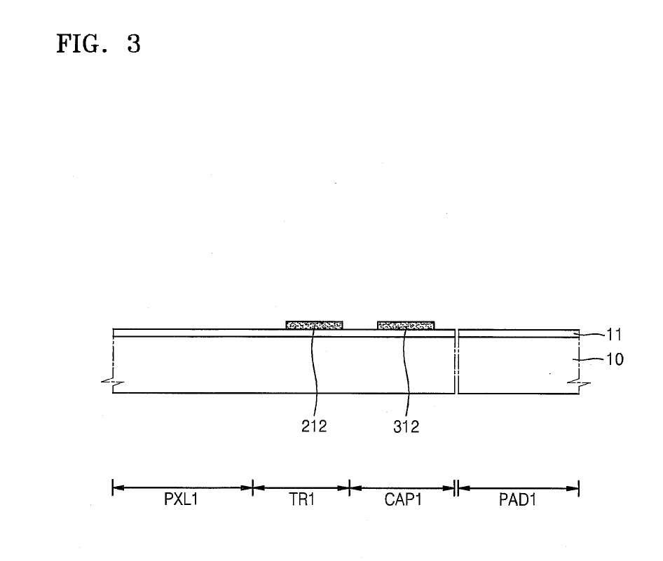

Hereinafter, a method of manufacturing the OLED display 1 will be described with reference to FIGS. 3 through 9.

FIG. 3 illustrates a cross-sectional view illustrating a first mask process for the OLED display 1, according to an exemplary embodiment.

Referring to FIG. 3, the buffer layer 11 is formed on the substrate 10, and a semiconductor layer (not shown) is formed on the buffer layer 11 and then is patterned so as to form the active layer 212 of the thin-film transistor and the first electrode 312 of the capacitor.

Although not illustrated, after photoresist (not shown) is coated on the semiconductor layer, the semiconductor layer is patterned via a photolithography process using a first photomask (not shown), so that the active layer 212 is formed. The photolithography process is processed in a manner that the first photomask is exposed by an exposure device (not shown), and then developing, etching, and stripping or ashing processes are sequentially performed.

The semiconductor layer can be formed of amorphous silicon or poly silicon. Here, the poly silicon can be formed by crystallizing the amorphous silicon. The crystallization of the amorphous silicon can be performed by using various methods including a rapid thermal annealing (RTA) method, a solid phase crystallization (SPC) method, an excimer laser annealing (ELA) method, a metal induced crystallization (MIC) method, a metal induced lateral crystallization (MILC) method, a sequential lateral solidification (SLS) method, and the like. However, a method for the semiconductor layer is not limited to the amorphous silicon or the poly silicon and can include an oxide semiconductor.

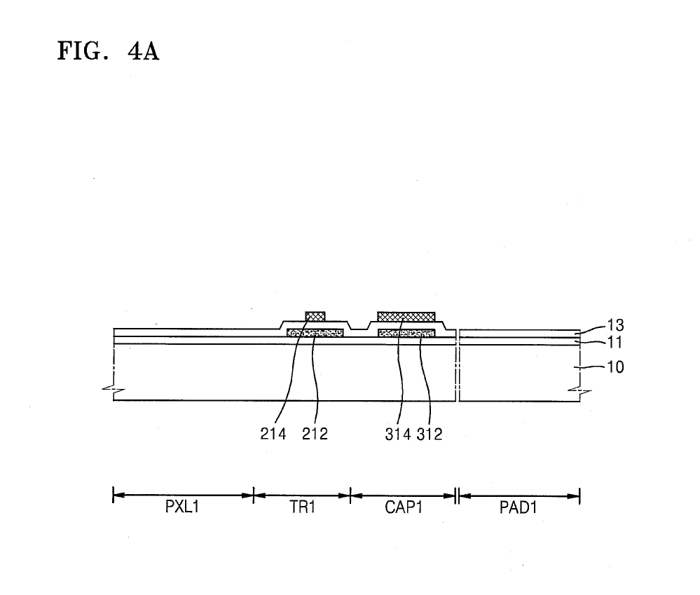

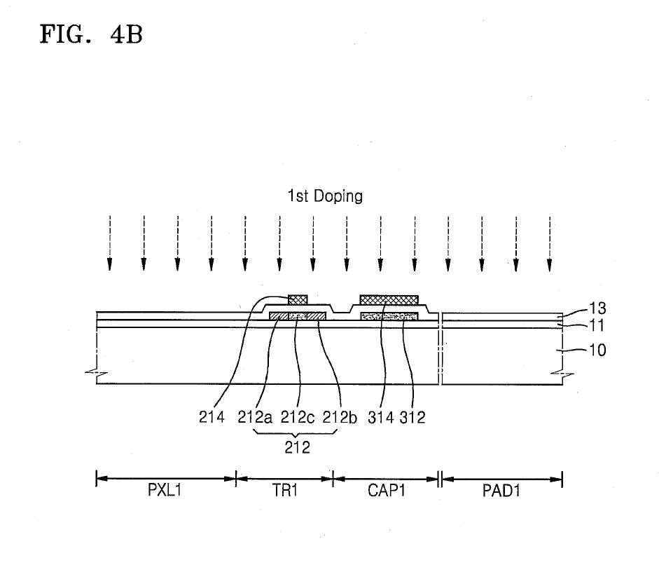

FIGS. 4A and 4B illustrate cross-sectional views illustrating a second mask process for the OLED display 1, according to an exemplary embodiment.

Referring to FIG. 4A, the gate insulating layer 13 is formed on the resultant of the first mask process shown in FIG. 3, and a first metal layer (not shown) is formed on the gate insulating layer 13 and is patterned. The first metal layer can be formed as a single layer or multiple layers formed of at least one metal material selected from Al, Pt, Pd, Ag, Mg, Au, Ni, Nd, Ir, Cr, Li, Ca, Mo, Ti, W, and Cu.

As a patterning result, the gate electrode 214 and an etching preventing layer 314 are formed on the gate insulating layer 13. The gate electrode 214 is formed while corresponding to the channel region 212c of the active layer 212, and the etching preventing layer 314 is formed while corresponding to the first electrode 312 of the capacitor.

Referring to FIG. 4B, ion impurity is first doped on the aforementioned structure. The ion impurity including b-type ion or p-type ion can be doped. Ion impurity with a density of at least about 1×10¹⁵ atoms/cm² can be doped while targeting the active layer 212 of the thin-film transistor.

The active layer 212 is doped with the ion impurity by using the gate electrode 214 as a self-align mask, so that the active layer 212 has the source region 212b and the drain region 212a, and the channel region 212c therebetween that are doped with the ion impurity.

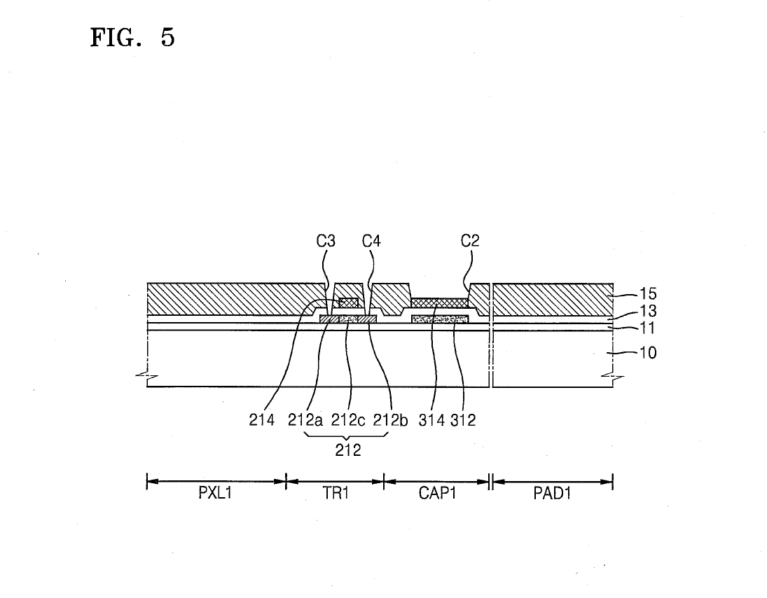

FIG. 5 illustrates a cross-sectional view of a resultant of a third mask process for the OLED display 1, according to an exemplary embodiment.

The interlayer insulating layer 15 is formed on a resultant of the second mask process shown in FIG. 4B, and is patterned so as to form contact holes C3 and C4 for exposing the source region 212b and the drain region 212a of the active layer 212, and the first opening C2 for exposing the etching preventing layer 314.

The third mask process of forming the contact holes C3 and C4 and the first opening C2 by patterning the interlayer insulating layer 15 can be performed by dry etching. The etching preventing layer 314 is formed on the first electrode 312 and prevents etching of the gate insulating layer 13 that operates as a dielectric layer in the present embodiment.

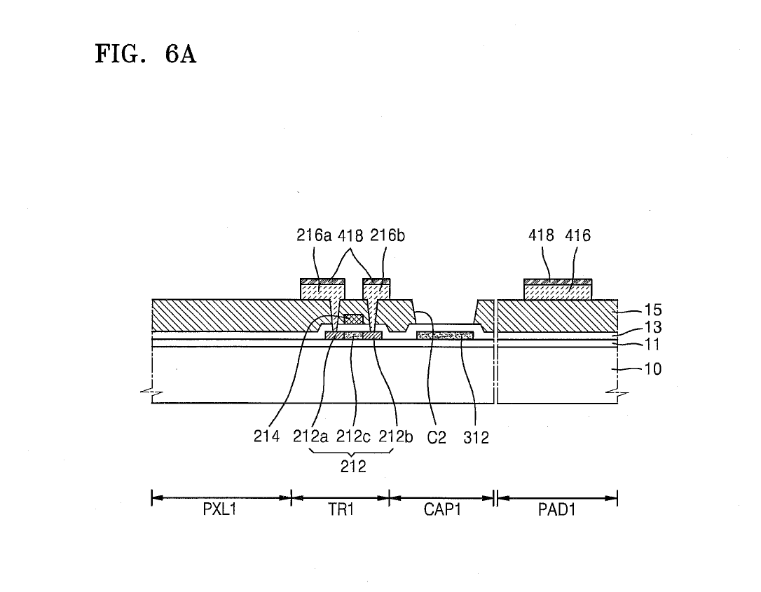

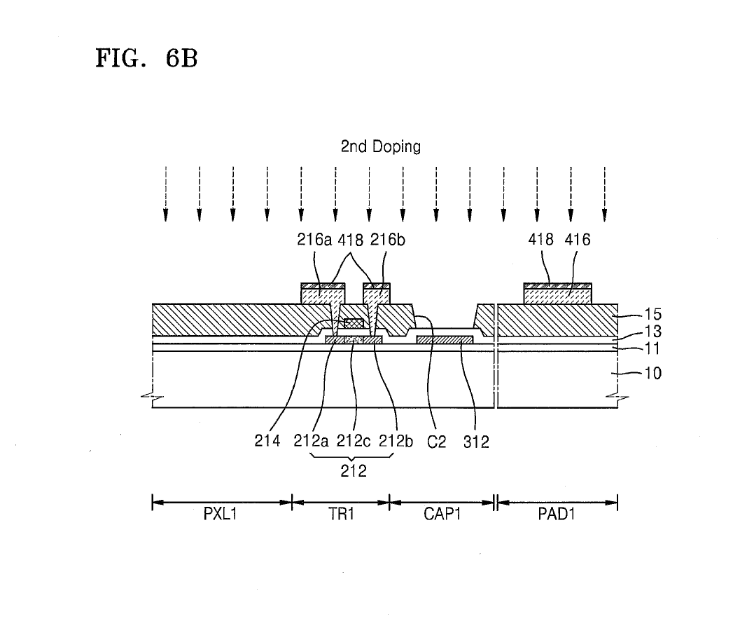

FIGS. 6A and 6B illustrate cross-sectional views illustrating a fourth mask process for the OLED display 1, according to an exemplary embodiment.

Referring to FIG. 6A, a second metal layer (not shown) and the protective layer 418 are formed on the resultant of the third mask process shown in FIG. 5 and are patterned so as to substantially simultaneously or concurrently form the source electrode 216b and the protective layer 418, the drain electrode 216a and the protective layer 418, and the pad electrode 416 and the protective layer 418.

Here, while the second metal layer and the protective layer 418 are patterned, the etching preventing layer 314 in the capacitor region CAP1 is removed along with the second metal layer on the etching preventing layer 314.

The second metal layer can be formed as at least two different metal layers having different electron mobilities. For example, the second metal layer is formed as at least two different metal layers formed of metal materials selected from Al, Pt, Pd, Ag, Mg, Au, Ni, Nd, Ir, Cr, Li, Ca, Mo, Ti, W, Cu, and an alloy thereof.

The protective layer 418 can be a transparent conductive oxide layer including at least one material selected from the group consisting of ITO, IZO, ZnO, In₂O₃, IGO, and AZO.

Referring to FIG. 6B, the aforementioned structure is secondly doped with ion impurities of a b-type or a p-type ion. Ion impurity with a density of at least about 1×10¹⁰ atoms/cm² can be doped while targeting the first electrode 312 of the capacitor. Due to the second doping, capacitance of the capacitor is increased.

Referring to FIG. 6B, only the first electrode 312 of the capacitor is doped, but in some embodiments, wirings that are formed on the same layer as the first electrode 312 and are connected to the first electrode 312 are also doped, so that an electric conductivity is increased.

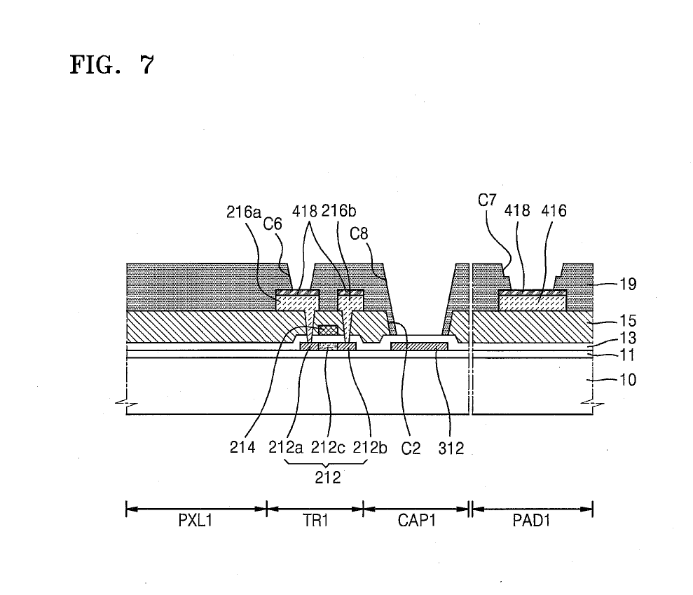

FIG. 7 illustrates a cross-sectional view illustrating a fifth mask process for the OLED display 1, according to an exemplary embodiment.

Referring to FIG. 7, the planarization layer 19 is formed on the resultant of the fourth mask process shown in FIG. 6B and is patterned, so that the contact hole C6 for exposing a portion of the drain electrode 216a, a contact hole C7 for exposing a top surface of the protective layer 418 on the pad electrode 416, and the second opening C8.

Referring to FIG. 7, the contact hole C6 is formed in the drain electrode 216a but embodiments are not limited thereto. That is, the contact hole C6 can be formed in the source electrode 216b.

The second opening C8 exposes a top surface of the gate insulating layer 13 formed on the first electrode 312 of the capacitor, and covers etched side surfaces of the first opening C2 formed in the interlayer insulating layer 15.

Since the interlayer insulating layer 15 is formed from an inorganic insulating layer and is patterned by dry etching, the etched side surfaces of the first opening C2 has a sharp slope, and an etched bottom surface of the first opening C2 is rough. However, in the present embodiment, since the planarization layer 19 formed from an organic insulating layer is patterned by wet etching and is formed in the first opening C2, the second opening C8 covers the etched side surfaces of the first opening C2, and thus, allows the sharp slope of the etched side surfaces to be gentle and improves a characteristic of the etched bottom surface.

The contact hole C7 is formed in the planarization layer 19 so as to expose the top surface of the protective layer 418 on the pad electrode 416. Since the thickness of the planarization layer 19 where the planarization layer 19 covers the edges of the pad electrode 416 is less than the thickness of the planarization layer 19 where the planarization layer 19 covers the source electrode 216b and the drain electrode 216a in the thin-film transistor region TR1, and is less than the thickness of the planarization layer 19 where the planarization layer 19 is between the interlayer insulating layer 15 and the pixel electrode 120 in the pixel region PXL1, it is possible to decrease a connection error that occurs at the pad electrode 416 while the external driver is connected.

The fifth mask process can be performed by using a half-tone mask (not shown).

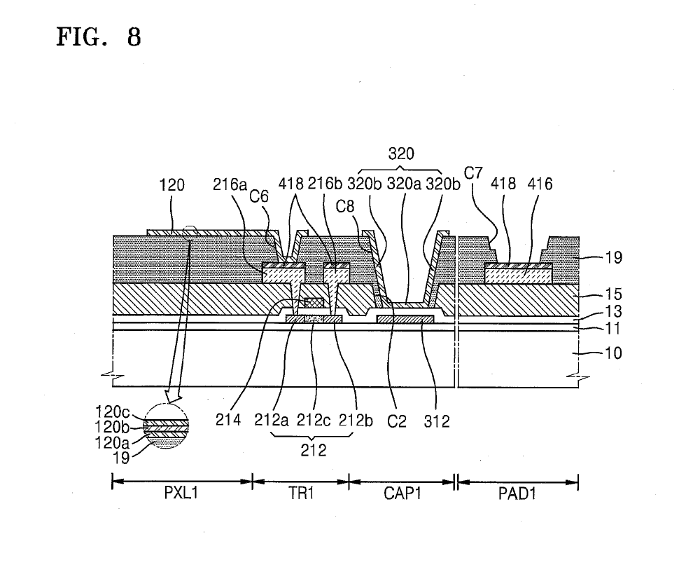

FIG. 8 illustrates a cross-sectional view illustrating a sixth mask process for the OLED display 1, according to an exemplary embodiment.

Referring to FIG. 8, a layer including a reflective material (not shown) is deposited and patterned on the resultant of the fifth mask process shown in FIG. 7, so that the pixel electrode 120 and the second electrode 320 of the capacitor are formed.

The pixel electrode 120 can include the first transparent conductive oxide layer 120a, the transflective metal layer 120b, and the second transparent conductive oxide layer 120c. Also, the second electrode 320 of the capacitor can be formed of the same material as the pixel electrode 120.

The second electrode 320 is formed in the second opening C8 formed in the planarization layer 19. The second electrode 320 includes the first portion 320a formed on the bottom of the second opening C8, and the second portion 320b formed on each of the side surfaces of the second opening C8.

One surface of the first portion 320a directly contacts the gate insulating layer 13, and one surface of the second portion 320b directly contacts the planarization layer 19.

Since the capacitor has the thin gate insulating layer 13 formed between the first electrode 312 and the second electrode 320 operates as a dielectric layer, capacitance of the capacitor can be increased.

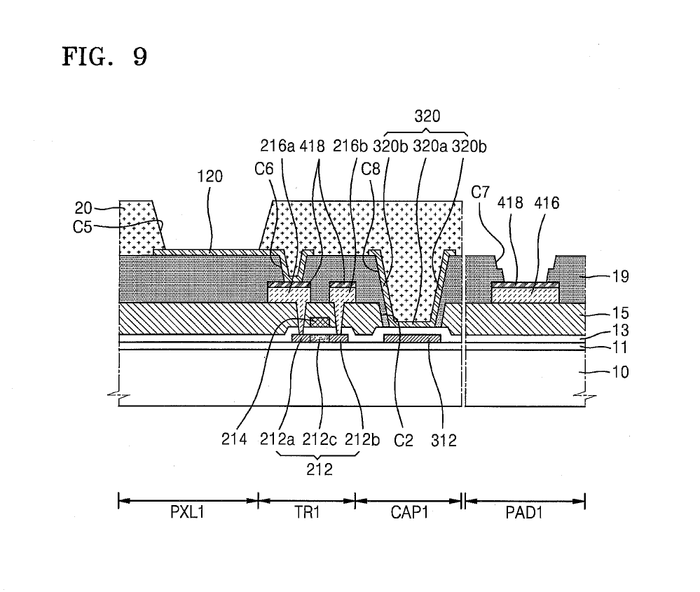

FIG. 9 illustrates a cross-sectional view illustrating a seventh mask process for the OLED display 1, according to an exemplary embodiment.

Referring to FIG. 9, the seventh mask process is performed to form the pixel-defining layer 20 on the resultant of the sixth mask process shown in FIG. 8 and then to form the opening C5 for exposing a top surface of the pixel electrode 120.

A top surface of the second electrode 320 of the capacitor directly contacts the pixel-defining layer 20.

The pixel-defining layer 20 can be an organic insulating layer formed of polymer derivatives having commercial polymers (PMMA and PS) and a phenol group, an acryl-based polymer, an imide-based polymer, an allyl ether-based polymer, an amide-based polymer, a fluorine-based polymer, a p-xylene-based polymer, a vinyl alcohol-based polymer, or a combination thereof.

An intermediate layer (not shown) including the emission layer 121 (refer to FIG. 2) is formed on the resultant of the seventh mask process shown in FIG. 9, and the opposite electrode 122 (refer to FIG. 2) is formed.

In the OLED display 1 according to exemplary embodiments, the first electrode 312 and the second electrode 320 of the capacitor are formed of the same materials as the doped active layer 212 and the pixel electrode 120, respectively, and only the gate insulating layer 13 is used as the dielectric layer. By doing so, the capacitance of the capacitor can be increased.

Also, since the pixel electrode 120 includes the transflective metal layer 120b, a luminescent efficiency of the OLED display 1 can be improved due to a micro-cavity structure.

Also, since the OLED display 1 is manufactured through the seven mask processes, the manufacturing costs can be reduced.

It should be understood that the exemplary embodiments described herein should be considered in a descriptive sense only and not for purposes of limitation. Descriptions of features or aspects within each exemplary embodiment should typically be considered as available for other similar features or aspects in other exemplary embodiments.

While the inventive technology has been described with reference to the figures, it will be understood by those of ordinary skill in the art that various changes in form and details can be made therein without departing from the spirit and scope as defined by the following claims.

What is claimed is:

1. An organic light-emitting diode (OLED) display, comprising:
a substrate;
a thin-film transistor comprising an active layer, a gate electrode, a source electrode, and a drain electrode formed over the substrate;
a gate insulating layer formed between the active layer and the gate electrode;
an interlayer insulating layer formed between the gate electrode and the source and drain electrodes;
a planarization layer formed over the source and drain electrodes;
a pixel electrode formed over the planarization layer;
a capacitor comprising a first electrode formed on the same layer as the active layer and a second electrode formed of the same material as the pixel electrode;
a pixel-defining layer covering opposing ends of the pixel electrode;
an emission layer formed over the pixel electrode; and
an opposite electrode formed over the emission layer.

2. The OLED display of claim 1, wherein the first electrode includes an ion impurity-doped semiconductor.

3. The OLED display of claim 1, wherein a bottom surface of the second electrode contacts the gate insulating layer.

4. The OLED display of claim 1, wherein a first opening is formed in the interlayer insulating layer and formed over the first electrode,
wherein a second opening is formed in the first opening and has a bottom surface having a width that is less than a width of a bottom surface of the first opening, and
wherein the second electrode is formed in the second opening.

5. The OLED display of claim 4, wherein the planarization layer covers side surfaces of the first opening.

6. The OLED display of claim 1, wherein a top surface of the second electrode contacts the pixel-defining layer.

7. The OLED display of claim 1, wherein the pixel electrode is formed of a reflective material, and wherein the opposite electrode is formed of a transparent material.

8. The OLED display of claim 7, wherein the pixel electrode comprises a second transparent conductive oxide layer, a transflective metal layer, and a first transparent conductive oxide layer that are sequentially stacked over the substrate.

9. The OLED display of claim 1, further comprising a protective layer is formed over the source and drain electrodes.

10. The OLED display of claim 9, wherein the protective layer is formed of a transparent conductive oxide.

11. The OLED display of claim 1, further comprising a pad electrode formed on the same layer as the source and drain electrodes.

12. The OLED display of claim 11, further comprising a protective layer formed of a transparent conductive oxide and formed over the pad electrode.

13. The OLED display of claim 11, wherein the thickness of the planarization layer where the planarization layer is formed over opposing sides of the pad electrode is less than the thickness of the planarization layer where the planarization layer is formed over the source and drain electrodes.

14. A method of manufacturing an organic light-emitting diode (OLED) display, the method comprising:
performing a first mask process including forming an active layer of a thin-film transistor and a first electrode of a capacitor over a substrate;
performing a second mask process including forming a gate insulating layer, forming a gate electrode of the thin-film transistor over the gate insulating layer, and forming an etching preventing layer in a region of the gate insulating layer corresponding to the first electrode;
performing a third mask process including forming an interlayer insulating layer, forming a contact hole in the interlayer insulating layer so as to expose a portion of the active layer, and forming a first opening in the interlayer insulating layer so as to expose the etching preventing layer;
performing a fourth mask process including forming source and drain electrodes of the thin-film transistor over the interlayer insulating layer, and removing the etching preventing layer;
performing a fifth mask process including forming a planarization layer, forming a contact hole so as to expose one of the source and drain electrodes in the planarization layer, and forming a second opening in the first opening;
performing a sixth mask process including forming a pixel electrode over the planarization layer and forming a second electrode of the capacitor in the second opening; and
performing a seventh mask process of forming a pixel-defining layer so as to cover the second electrode and opposing sides of the pixel electrode.

15. The method of claim 14, further comprising doping a resultant of the second mask process with ion impurities following the performing of the second mask process.

16. The method of claim 14, wherein, in the third mask process, dry etching the interlayer insulating layer so as to form the contact hole and the first opening.

17. The method of claim 14, further comprising doping a resultant of the fourth mask process with ion impurities following the performing of the fourth mask process.

18. The method of claim 14, wherein the performing of the fourth mask process further includes forming a pad electrode concurrently with the source and drain electrodes.

19. The method of claim 18, wherein the thickness of the planarization layer where the planarization layer is formed over opposing sides of the pad electrode is less than the thickness of the planarization layer where the planarization layer is formed over the source and drain electrodes.

20. The method of claim 14, further comprising:
forming an emission layer over the pixel electrode following the performing of the seventh mask process; and
forming an opposite electrode over the emission layer.
